(19) United States
(12) Patent Application Publication
(10) Pub. No.: US 2009/0205694 A1
(43) Pub. Date: Aug. 20, 2009

(54) Thermoelectric Generation Device for Energy Recovery

(76) Inventors: Cary M. Huettner, Rochester, MN (US); Joseph Kuczynski, Rochester, MN (US); Robert E. Meyer, III, Rochester, MN (US); Timothy J. Tofil, Rochester, MN (US)

Correspondence Address: IBM-Rochester c/o Toler Law Group, 8500 Bluffstone Cove, Suite A201, Austin, TX, 78759, US

(21) Appl. No.: 12/033,058

(22) Filed: Feb. 19, 2008

(51) Int. Cl. H01L 35/28; H01L 35/02

(52) U.S. Cl. 136/201; 136/200; 136/204; 136/224; 136/238; 136/239; 136/240; 136/241

(57) ABSTRACT

A thermoelectric generation device is configured for mounting on cooling tubes of a heat exchanger of a computer room air conditioning unit in a data center. A first type of Seebeck material and a second type of Seebeck material are arranged in a matrix and connected in series. An electrically insulating, but thermally conducting plate is located on either side of the device. The device is mounted physically on cooling tubes of the heat exchanger and exposed on the other side to the warm air environment. As a result of the temperature difference a voltage is generated that may be used to power an electrical load connected thereto.

### FIELD OF THE INVENTION

The present invention relates generally to a thermoelectric generation device. More particularly, the invention relates to a thermoelectric generation device for use in data centers having computer room air conditioning (CRAC) units for recovering energy generated in the form of heat by computers in the data center, and converting such energy into electricity. The electricity is then put into the data center, peripherals, or into the electric grid.

### BACKGROUND OF THE INVENTION

Data centers are facilities used to house computer systems and associated components, such as telecommunications and storage systems. Data centers typically include redundant, or back up power supplies, redundant data communications connections, environmental controls (air conditioning, fire suppression, etc.), and special security devices. Information Technology (IT) operations are a crucial aspect of most organizational operations and are supported by such data centers. Because of the large number of systems housed, a significant amount of heat is generated requiring strict control of the physical environment of the data center.

In a typical data center, air conditioning is used to keep the room cool and may be also used for humidity control. The primary goal of a data center air conditioning system is to keep several components at the board level operating within the manufacturer's specified temperature and humidity range. This environmental control is crucial since electronic equipment in a confined space generates excessive heat and tends to malfunction if not adequately cooled. In a typical data center the generated thermal energy is dissipated into the operating environment. The energy results in an increase of temperature and an increased demand on the cooling infrastructure, which in turn results in an increased utility cost.

One prior art method of converting temperature differences into electricity is achieved through a physics phenomenon known as the Seebeck effect. A voltage, referred to as the thermoelectric EMF, is created in the presence of a temperature difference between two different metals or semiconductors. This causes a continuous current to flow in the conductors if they form a complete loop. The voltage created is on the order of several microvolts per degree difference.

FIG. 1 is a simple circuit illustrating how electricity may be generated from a temperature difference. In circuit 11, two thermocouples, T₁ and T₂, are connected with two different metals or semiconductors, A and B. One thermocouple, T₁ or T₂, is in contact with a hot surface or side, and the other thermocouple, T₁ or T₂, respectively, is in contact with a cooler surface or side. This causes a continuous current to flow in the conductors when they form a complete loop.

Referring again to the circuit 11 illustrated in FIG. 1, the voltage developed may be derived from the equation

$$V = {\int }_{T 1}^{T 2} ( {S}_{B} ( T ) - {S}_{A} ( T ) ) d T .$$

In this equation, S_{A} and S_{B} are the Seebeck coefficients (also referred to as thermoelectric power or thermopower) of the metals or semiconductors A and B. T₁ and T₂ are the temperatures of the two junctions at the two thermocouples. As may be appreciated, the Seebeck coefficients are non-linear and depend upon the conductors' absolute temperature, material and molecular structure. If the Seebeck coefficients are effectively constant for the measured temperature range, the previous formula may be approximated as: V=(S_{B}−S_{A})*(T₂−T₁).

The Seebeck coefficient of a material is a measure of the magnitude of an induced thermoelectric voltage in response to a temperature difference across that material. An applied temperature difference causes charged carriers in the material, irrespective of whether they are electrons or holes, to diffuse from the hot side to the cold side. Charged carriers migrating to the cold side leave behind their oppositely charged immobile nuclei at the hot side, giving rise to a thermoelectric voltage. Thermoelectric refers to the fact that the voltage is created by a temperature difference. The current obtainable from such a device depends upon the surface area of the materials.

A thermocouple connection such as that illustrated by circuit 11 of FIG. 1 has in the past been used primarily for temperature measurement. In such devices the charged carrier movement in the conducting or semiconducting material generates a Seebeck voltage typically on the order of mV. A typical Seebeck thermoelectric generation device uses n-type and p-type structures that are typically doped silicon interconnected to provide a conducting path. The doping provides a sufficiently different Seebeck coefficient so that (S_{B}−S_{A}) is a non-zero value.

Recent energy shortages throughout the world have raised awareness of the desirability of using “green” technologies to conserve energy. Given the large amount of wasted heat generated by data centers, it becomes desirable to provide a system and method in which such wasted heat may be recovered and reused in an alternative form of energy.

### SUMMARY OF THE INVENTION

The present invention provides an improved energy recovery system, including a thermoelectric generation device arranged in size, shape and number to be mounted to substantially and completely surround at least one cooling tube of a heat exchanger of a CRAC of the type typically used in data centers. A plurality of alternating Seebeck A and Seebeck B conducting material pillars may be arranged in a matrix. For purposes of this disclosure, Seebeck materials used are exemplified. In implementation, two different types of Seebeck materials are used, and are identified as “Seebeck A” and “Seebeck B,” or “Seebeck A material” or “Seebeck B material.” First electrical connection pads connect alternating pairs of Seebeck A and Seebeck B conducting material pillars at one end of the pillars. Second electrical connection pads connect the alternating pairs of Seebeck A and Seebeck B conducting material pillars at another end of the pillars in a manner establishing a series electrical connection. Such a device is mounted on a cooling tube of a heat exchanger with one side contacting the cooling tubes and making up the cold side, and the other side exposed to the environment of a data center and making up the hot side, to thereby generate a voltage.

According to one aspect of the invention, a pair of electrically insulating and thermally conducting plates are mounted on respective ends of Seebeck A and Seebeck B conducting material pillars in contact with the electrical connection pads on either side and in contact or exposed to respective hot and cold sides.

Embodiments may include semiconducting materials selected from a specific group (the materials for Seebeck A and Seebeck B pillars), and are selected such that the value of (S_{B} −S_{A}) is as large as practical.

Another aspect of the invention includes a combination of a plurality of thermoelectric generation devices and a heat exchanger as substantially previously described, and with the thermoelectric generation devices substantially and completely surrounding respective cooling tubes of a plurality of cooling tubes.

Yet another aspect of the invention is a method of recovering current from a heat exchanger. The method includes attaching thermoelectric generation devices of the type previously described to cooling pipes of a heat exchanger in a manner surrounding at least in part the cooling pipes of the heat exchanger. In one embodiment the entire cooling pipe is substantially surrounded. Such thermoelectric generation devices may be connected to an electrical load. The heat exchanger may be operated to cause the thermoelectric generation devices to generate a current.

These and other advantages and features that characterize the invention are set forth in the claims appended hereto and forming a further part hereof. However, for a further understanding of the invention, and of the advantages and objectives attained through its use, reference should be made to the Drawings and to the accompanying descriptive matter in which there are described exemplary embodiments of the invention.

### BRIEF DESCRIPTION OF THE DRAWINGS

FIG. 1 is a simple circuit illustrating how the Seebeck effect may be used to generate voltages.

FIG. 2 is a perspective view of a typical heat exchanger for use in a CRAC of a data center.

FIG. 3 is a perspective view of an exemplary embodiment of a thermoelectric generation device in accordance with the principles of the present invention.

FIG. 4 is a table listing desirable materials to be used as Seebeck materials in the device of the invention.

FIG. 5 is a schematic diagram illustrating a typical connection for the device in accordance with the underlying principles of the present invention connected to an electrical load.

FIG. 6 is a cross-sectional partial view illustrating a device in accordance with the invention mounted on a cooling tube of a heat exchanger of the type used in a CRAC for a data center.

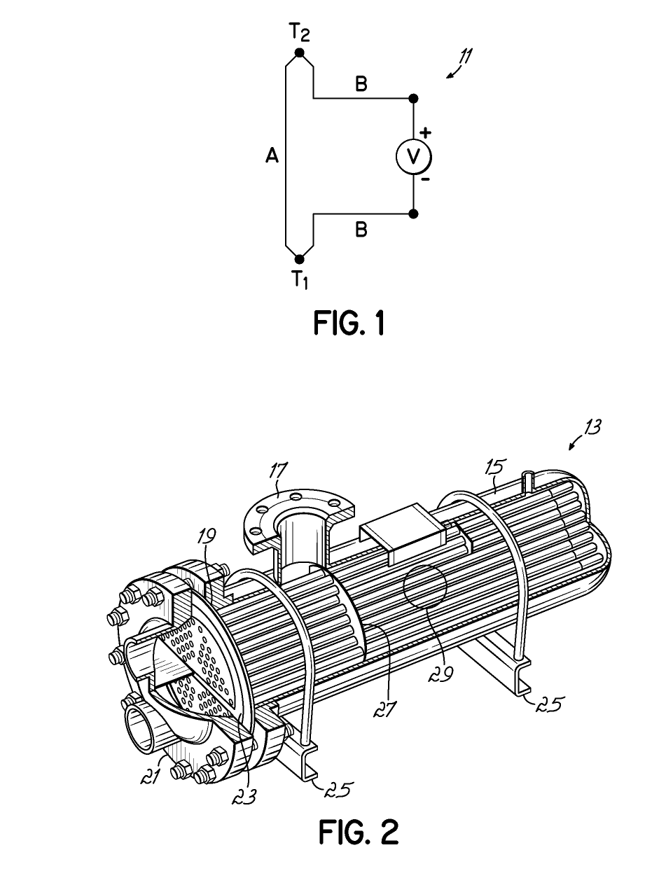

### DETAILED DESCRIPTION OF THE PREFERRED EMBODIMENTS

In one aspect, embodiments consistent with the invention may capitalize on the heat generated by computers and peripherals in data centers and the cooling provided by CRACs, including heat exchangers. In this manner, a thermoelectric generation device implementing the Seebeck effect may be utilized to recycle heat in the form of waste thermal energy to generate electricity. The generated electricity may be used to offset utility costs or power other devices, thus reducing the carbon footprint of the data center.

FIG. 2 illustrates a representative heat exchanger 13 of the type used with CRACs in data centers. The heat exchanger 13 includes a shell 15. Connections 17 are used to provide chilling fluid (typically chilled water) to cooling tubes 29 making up the heat exchanger. The connections 17 thus provide a flow of chilled fluid through the cooling tubes 29. Conventionally, the heat exchanger 13 includes a tube sheet 19, head 21, gaskets 23, baffles 27 and mountings 25, all of which are conventional and well known to those of ordinary skill in the art.

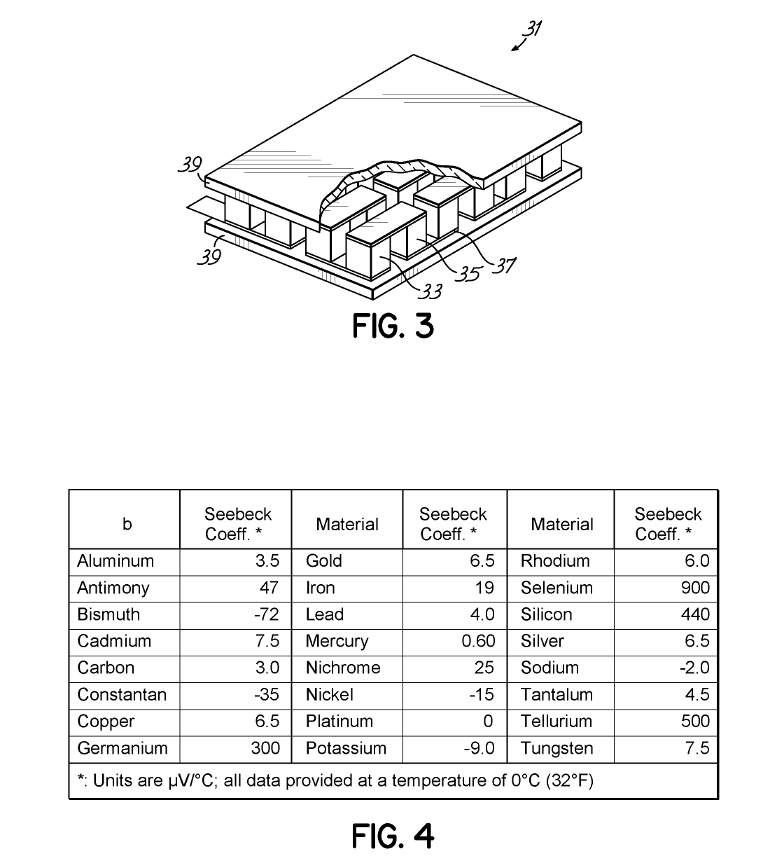

An exemplary configuration of a thermoelectrical generating device utilizing the Seebeck effect employed in an embodiment of the invention is illustrated in FIG. 3. The device 31 includes pillars 33 and 35 of Seebeck A and Seebeck B conducting material. Copper pads 37 interconnect the pillars 33 and 35 in a series arrangement as part of a matrix of pillars 33 and 35. Electrically insulating and thermally conducting plates 39 may be placed adjacent either end of the pillars 33 and 35 on top of the conducting pads 37. The conducting pads are in one embodiment made of copper. The conducting plates 39 are optionally of ceramic material, and by connecting the pairs of pillars 33 and 35 in series, relatively high voltages may be obtained.

In exemplary Seebeck type devices of the invention, Seebeck A and Seebeck B conducting material pillars 33 and 35 are preferably made of those materials listed in the table of FIG. 4 as discussed hereafter. Seebeck A material is different from Seebeck B material by virtue of having a different Seebeck coefficient. Materials are not limited to those listed in the table, which are merely exemplary of advantageous Seebeck materials for use with the invention as will be discussed hereafter. The selected materials have sufficiently different Seebeck coefficients such that the value of (S_{B}−S_{A}) is non-zero. The materials shown in the table of FIG. 4 are conductive metals. By fabricating the Seebeck A and Seebeck B conducting material pillar pairs in series, a fairly sizeable voltage may be attained, notwithstanding a relatively small Seebeck coefficient delta.

As noted previously, FIG. 4 is a table listing materials exemplary of those preferred for use in accordance with the invention. More specifically, the materials selected in one embodiment are not doped silicon as conventional devices, but are selected from the materials listed in the table of FIG. 4.

The power output may be dependent upon selection of the Seebeck materials for the hot and cold interfaces, as well as the surface area of the two junctions. For example, a device with Selenium and Bismuth faces may produce (972)*(22.2 C)=21.6 mV.

A typical CRAC heat exchanger 13 includes multiple cooling tubes 29, usually between about 20 to 40 individual tubes, each of which is roughly four feet in length and six inches in diameter. This results in an available surface area of 0.58 m² per cooling tube 29.

Using ten tubes as a representative example, and with Se and Bi as the selected materials, this results in 12.6 W/CRAC unit. As an alternative to using only the materials in the table of FIG. 4, it is noted that by incorporating other elements into Bi such as Indium as a dopant, the current density may be increased up to 100 mA/Cm² or higher as will be apparent to those of ordinary skill in the art. This may increase generated power by an order of magnitude. The foregoing example is nonlimiting and illustrates how material modifications may be used to increase current density. By selectively combining materials, theoretical current densities approaching one A/cm² may be achieved, generating over a kilowatt of power in a small heat exchanger employing only ten cooling tubes 29 for a CRAC unit.

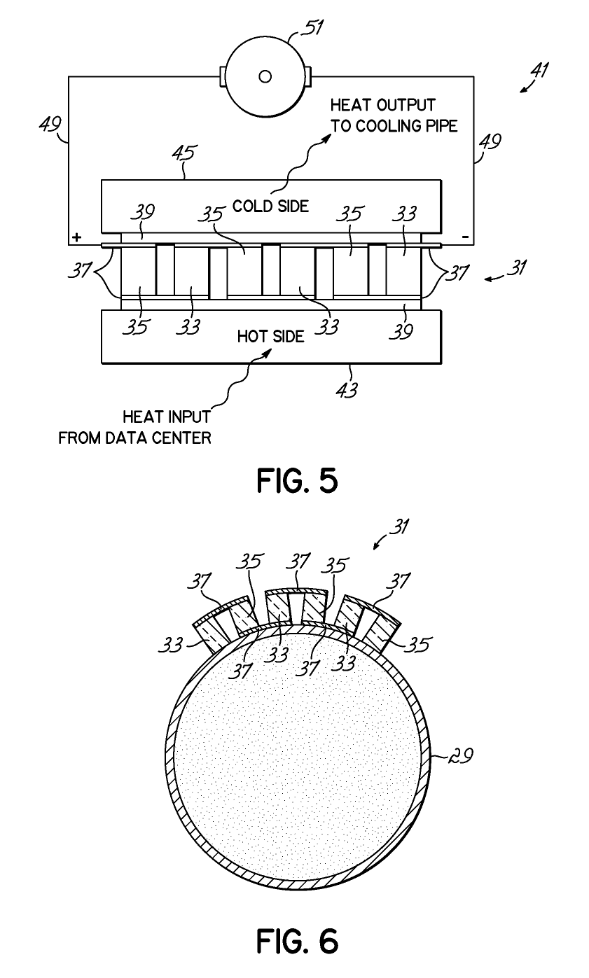

FIG. 5 illustrates a typical arrangement 41 in which the thermoelectric generating device 31 may be connected to conducting leads 49 and to an electrical load 51 such as the grid, or devices in the data center, etc. The device 31 may be connected through nonelectrically conducting, but thermally conducting plates 39. The conducting plates 39 typically comprises ceramic material in contact on one side with the cooling tubes 29, and making up a cool side 45. Heat is radiated into the cooling tubes 29 from a hot side 43. The hot side 43 may be exposed to the ambient environment in the data center.

FIG. 6 illustrates a specific mounting arrangement on a cooling tube 29. The arrangement includes a thermoelectric generation device 31, shown in partial view, with Seebeck A and Seebeck B conducting material pillars 33 and 35 interconnected through copper pads 37. In a specific embodiment, the arrangement of pillars 33 and 35 substantially completely surrounds the cooling tube 29 and extends substantially along the entire length thereof. The arrangement is shown only in a partial view not completely surrounding the cooling tube 29. In addition, for ease of understanding, the conducting plates 39 are not shown. The area shown as “hot side” and “cold side” are not actual structures, but indicative of temperature regions.

While the invention has been described in terms of conventional circuit arrangements, in a more specific embodiment, it will be appreciated by those of ordinary skill in the art that nanotechnology may be used to increase the surface area of the Seebeck materials making up the conductors. More specifically, nanorods copper plated with appropriate Seebeck materials may increase the surface area of a flat plate multiple orders of magnitude, for example, by a factor of 50.

While the present invention is being illustrated by a description of various embodiments and while these embodiments have been described in considerable detail, it is not the intention of the Applicants' to restrict, or any way limit the scope of the appended claims to such detail. For instance, because the Seebeck effect is well understood and documented, many aspects of the invention had been described in terms of conventional Seebeck based concepts. However, the Seebeck based concepts are used principally for ease of explanation. The invention in its broader aspects is therefore not limited to the specific details, representative apparatus and method and illustrative example shown and described. Accordingly, departures may be made from such details without departing from the spirit or scope of Applicants' general inventive concept.

What is claimed is:

1. A thermoelectric generation device, comprising:
a plurality of alternating Seebeck A and Seebeck B conducting material pillars arranged in a matrix;
first electrical connection pads connecting alternating pairs of Seebeck A and Seebeck B conducting material pillars at one end of said pillars;
second electrical connection pads connecting said alternating pairs of Seebeck A and Seebeck B conducting material pillars at another end of said pillars in a manner establishing a series electrical connection; and
said arrangement of Seebeck A and Seebeck B conducting material pillars, first electrical connection pads and second electrical connection pads arranged in shape and number to be mounted on a cooling tube of a heat exchanger of a computer room air conditioner (CRAC).

2. The thermoelectric generation device of claim 1, further comprising a CRAC heat exchanger having a plurality of cooling tubes, and each cooling tube having a respective thermoelectric generation device mounted thereon in a manner substantially and completely surrounding a respective cooling tube.

3. The thermoelectric generation device of claim 1, further comprising a pair of electrically insulating and thermally conducting plates mounted on respective ends of said Seebeck A and Seebeck B conducting material pillars in respective contact with said first electrical connection pads and said second electrical connection pads.

4. The thermoelectric generation device of claim 1, wherein said Seebeck A material pillars have a substantially different Seebeck coefficient from that of said Seebeck B conducting material pillars.

5. The thermoelectric generation device of claim 4, wherein said Seebeck A and Seebeck B conducting material pillars are selected from the group consisting of: aluminum, antimony, bismuth, cadmium, carbon, constantan, copper, germanium, gold, iron, lead, mercury, nichrome, nickel, platinum, potassium, rhodium, selenium, silicon, silver, sodium, tantalum, tellurium and tungsten, and said Seebeck A conducting material being different from said Seebeck B conducting material.

6. The thermoelectric generation device of claim 3, wherein said plates include ceramic material.

7. The thermoelectric generation device of claim 1, wherein said electrical connection pads include copper.

8. The thermoelectric generation device of claim 5, wherein the voltage output of said device satisfies the equation V=(S_{B}−S_{A})*(T₂−T₁); wherein V is voltage, S_{B} is the Seebeck coefficient of one of the Seebeck A and Seebeck B conducting material pillars, S_{A} is the Seebeck coefficient of the other of the Seebeck A and Seebeck B conducting material pillars, T₂ and T₁ are the temperatures at the hot and cold interfaces of the device, and wherein the materials selected for the Seebeck A and Seebeck B conducting material pillars are such that (S_{B}−S_{A}) is non-zero.

9. The thermoelectric generation device of claim 2, wherein said plurality of cooling tubes comprises about 20 to about 40 tubes.

10. The thermoelectric generation device of claim 8, wherein the materials for the Seebeck A and Seebeck B conducting material pillars are selected such that the value of (S_{B}−S_{A}) is as large as practical.

11. In combination, a plurality of thermoelectric generation devices and a heat exchanger, said combination comprising:
a heat exchanger having a plurality of cooling tubes;
a plurality of thermoelectric generation devices, each comprising:
a plurality of alternating Seebeck A and Seebeck B conducting material pillars arranged in a matrix;
first electrical connection pads connecting alternating pairs of Seebeck A and Seebeck B conducting material pillars at one end of said pillars to define one of a hotter surface and a cooler surface interface; and
second electrical connection pads connecting said alternating pairs of Seebeck A and Seebeck B conducting material pillars at another end of said pillars in a manner establishing a series electrical connection defining the other of said hotter surface and cooler surface interface; and
said plurality of thermoelectric generation devices of size, shape and number substantially and completely surrounding a respective cooling tube of said plurality of cooling tubes with a cooler surface interface thereof mounted on said respective one of said plurality of cooling tubes.

12. The combination according to claim 11, further comprising a pair of electrically insulating and thermally conducting plates mounted on respective ends of said Seebeck A and Seebeck B conducting material pillars in respective contact with said first electrical connection pads and said second electrical connection pads.

13. The combination according to claim 11, wherein said Seebeck B conducting material pillars have a substantially different Seebeck coefficient from that of said Seebeck A conducting material pillars.

14. The combination according to claim 11, wherein said Seebeck A and Seebeck B conducting material pillars are selected from the group consisting of: aluminum, antimony, bismuth, cadmium, carbon, constantan, copper, germanium, gold, iron, lead, mercury, nichrome, nickel, platinum, potassium, rhodium, selenium, silicon, silver, sodium, tantalum, tellurium and tungsten, and said Seebeck B conducting material being different from said Seebeck A conducting material.

15. A combination according to claim 11, wherein the voltage output of said device satisfies the equation V=(S_{B}−S_{A})·(T₂−T₁), wherein V is voltage, S_{B} is the Seebeck coefficient of one of the Seebeck A and Seebeck B conducting materials, S_{A} is the Seebeck coefficient of the other of the Seebeck A and Seebeck B conducting materials, T₂ and T₁ are the temperatures at the hot and cold interfaces of the device, and wherein the materials selected for the Seebeck conducting materials are such that (S_{B}−S_{A}) is non-zero.

16. A method of recovering current from a heat exchanger, comprising:
attaching at least one thermoelectric generation device to cooling pipes of a heat exchanger;
connecting said at least one thermoelectric generation device to an electrical load;
the at least one electric generation device comprising:
a plurality of alternating Seebeck A and Seebeck B conducting material pillars arranged in a matrix;
first electrical connection pads connecting alternating pairs of Seebeck A and Seebeck B conducting material pillars at one end of said pillars; and
second electrical connection pads connecting said alternating pairs of Seebeck conducting pillars at another end of said pillars in a manner establishing a series electrical connection; and
operating said that heat exchanger to cause the at least one thermoelectric generation device to generate a current.

17. The method of claim 16, comprising conducting said method on a CRAC heat exchanger having a plurality of cooling tubes, each cooling tube having a respective thermoelectric generation device mounted thereon in a manner substantially and completely surrounding a respective cooling tube.

18. The method of claim 16, whereon a pair of electrically insulating and thermally conducting plates are mounted on respective ends of said Seebeck A and Seebeck B conducting material pillars in contact respectively, with said first electrical connection pads and said second electrical connection pads.

19. The method of claim 16, wherein said Seebeck A and Seebeck B conducting material is selected from the group consisting of: aluminum, antimony, bismuth, cadmium, carbon, constantan, copper, germanium, gold, iron, lead, mercury, nichrome, nickel, platinum, potassium, rhodium, selenium, silicon, silver, sodium, tantalum, tellurium and tungsten, and said Seebeck A conducting material is different from said Seebeck B material.

20. The method of claim 16, wherein the voltage output of said device satisfies the equation V=(S_{B}−S_{A}) (T₂−T₁), wherein V is voltage, S_{B} is the Seebeck coefficient of one of the Seebeck A and Seebeck B conducting materials, S_{A} is the Seebeck coefficient of the other of the Seebeck A and Seebeck B conducting materials, T₂ and T₁ are the temperatures at the hot and cold interfaces of the device, and wherein the materials selected for the Seebeck A and Seebeck B conducting material pillars is such that (S_{B}−S_{A}) is non-zero.

21. The method of claim 19, wherein said Seebeck A and Seebeck B materials are metal doped with another material.

22. The method of claim 19, wherein one of said Seebeck A and Seebeck B materials is Bismuth doped with Indium and the other of said Seebeck A and Seebeck B materials is Selenium.

23. A thermoelectric generation device, comprising:
a plurality of alternating Seebeck A and Seebeck B conducting material pillars arranged in a matrix;
first electrical connection pads connecting alternating pairs of Seebeck A and Seebeck B conducting material pillars at one end of said pillars;
second electrical connection pads connecting said alternating pairs of Seebeck A and Seebeck B conducting material pillars at another end of said pillars in a manner establishing a series electrical connection;
said arrangement of Seebeck A and Seebeck B conducting material pillars, first electrical connection pads and second electrical connection pads arranged in shape and size to be mounted on a cooling tube of a heat exchange of a computer room air conditioner (CRAC); and
said Seebeck A and Seebeck B conducting material pillars are metals comprising at least one of aluminum, carbon, constantan, copper, germanium, gold, iron, lead, mercury, nichrome, nickel, platinum, potassium, rhodium, selenium, silicon, silver, sodium, tantalum, tellurium and tungsten, and said Seebeck A and conducting material being different from said Seebeck B conducting material.

24. The thermoelectric generation device of claim 23, whereas one of said Seebeck A material and Seebeck B material is selenium and the other is bismuth.

25. The thermoelectric generation device of claim 24, wherein said bismuth material is doped with indium.
